(19) United States
(12) Patent Application Publication
(10) Pub. No.: US 2005/0181313 A1
(43) Pub. Date: Aug. 18, 2005

(54) Method for forming openings in a substrate using a packing and unpacking process

(76) Inventors: Jen-Chieh Shih, YongKang City (TW); Bang-Chein Ho, Hsa-Chu (TW)

Correspondence Address: DUANE MORRIS, LLP;IP DEPARTMENT, ONE LIBERTY PLACE, PHILADELPHIA, PA, 19103-7396, US

(21) Appl. No.: 10/780,946

(22) Filed: Feb. 18, 2004

(51) Int. Cl. G03F 7/00

(52) U.S. Cl. 430/394; 430/322

(57) ABSTRACT

A method and system is disclosed for selectively forming photoresist patterns for making openings in a substrate. A layer of photoresist is deposited on the substrate which contains one or more types of photoresist dissolving agent generators. A first set of areas of the photoresist is exposed to a first light source through a first mask to activate a photoresist dissolving agent generator of a first type to release a first photoresist dissolving agent in the first set of areas. Then, a second set of areas of the photoresist is also exposed to a second light source through a second mask to activate a photoresist dissolving agent generator of a second type to release a second photoresist dissolving agent in the second set of areas. The second set of areas is a sub set of the first set of areas such that the first and second photoresist dissolving agents in the second set of areas neutralize each other to protect the second set of areas from being used as the patterns for forming the openings.

### BACKGROUND OF INVENTION

This disclosure relates generally to the field of semiconductor manufacturing and, more specifically, to the use of a single photoresist layer containing both a photoacid generator and a photobase generator, or the use of both a single photoresist layer containing a photoacid generator and a water-soluble film containing a photobase generator to achieve a packing-and-unpacking process.

A packed-and-unpacked process generally combines a packed contact hole pattern photomask and an unpacked contact hole pattern photomask to produce a quality pattern with well-defined critical dimensions in a photoresist layer and on an etched substrate. The packed pattern is a combination of desired contact holes and also undesired contact holes that are added to densify the first photomask. The packed pattern photomask is utilized to expose and develop the combined pattern of desired and undesired contact holes in a first layer of photoresist. There are two variations that allow the unpacked pattern to achieve the selection of desired contact holes into the final photoresist pattern. The first variation defines islands in the second photoresist layer that are slightly larger than the undesired contact holes in the first photoresist layer and therefore securely cover them. These photoresist islands in the second photoresist layer, in the first variation, are based on the undesired contact holes in the first photoresist layer. The second variation defines larger areas in the second photoresist layer that cover not only the undesired holes in the first photoresist layer, but also the broader areas between the desired contact holes. The remaining openings in the second photoresist layer, over the desired contact holes in the first photoresist layer, are slightly larger than those desired contact holes in the first photoresist layer. The remaining openings in the second photoresist layer, in the second variation, are based on the desired contact holes in the first photoresist layer.

Photoresists are photosensitive films used for the transfer of images to a substrate. A coating layer of a photoresist is formed on a substrate and the photoresist layer is then exposed through a photomask to a source of activating radiation. The photomask has areas that are opaque to activating radiation and other areas that are transparent to activating radiation. Exposure to activating radiation provides a photoinduced transformation of the photoresist coating thereby transferring the pattern of the photomask to the photoresist-coated substrate. Following the exposure, the photoresist is developed to provide a relief image that permits selective processing of a substrate.

A photoresist can be either positive-acting or negative-acting. For most negative-acting photoresists, those coating layer portions that are exposed to activating radiation polymerize or crosslink in a reaction between a photoactive compound and polymerizable reagents of the photoresist composition. Consequently, the exposed coating portions are rendered less soluble in a developer solution than unexposed portions. For a positive-acting photoresist, exposed portions are rendered more soluble in a developer solution while areas not exposed remain comparatively less soluble. In general, photoresist compositions comprise at least a resin binder component and a photoactive agent.

More recently, chemically-amplified-type resists have been increasingly employed, particularly for formation of sub-micron images and other high-performance applications. A chemically-amplified photoresist contains a polymer, which is not photoactive, a solvent, and a photoacid generator and/or a photobase generator. Such photoresists may be negative-acting or positive-acting and generally include many crosslinking events (in the case of a negative-acting resist) or deprotection reactions (in the case of a positive-acting resist) per unit of photogenerated acid. In the case of positive chemically-amplified resists, certain cationic photoinitiators have been used to induce cleavage of certain “blocking” groups pendant from a photoresist binder, or cleavage of certain groups that comprise a photoresist binder backbone. Upon cleavage of the blocking group through exposure of a coating layer of such a resist, a polar functional group is formed, which results in different solubility characteristics in exposed and unexposed areas of the resist coating layer.

In the case of a chemically-amplified, positive resist, in which a photoacid generator (PAG), which generates acid under ultra-violet (UV) light exposure, is added, protective groups are deprotected by heating after exposure, in a post-exposure bake (PEB). The acid formed during exposure, and activated during PEB, serves as a catalyst which causes the deprotection reaction to proceed along the polymer chain. The acid cleaves the polymer into smaller molecules with considerably different polarity and solubility in developer solution. The developer produces the exposed pattern in the resist layer. If a photobase generator is added, then an exposure by a different UV light wavelength, or an exposure for a different time, can activate formation of a chemical base, which can selectively neutralize the previously generated acid and thereby prevent its reaction with the polymer. What is needed is an improved method for carrying out the packing-and-unpacking process.

### SUMMARY

The present invention is directed to a photoresist process for fabricating integrated circuit devices, (ICs). A single photoresist layer is coated onto a substrate and both a photomask with a packed pattern and a photomask with an unpacked pattern are utilized to expose the photoresist layer.

In one example, a layer of photoresist which contains one or more types of photoresist dissolving agent generators is deposited on a substrate. A first set of areas of the photoresist is exposed to a first light source through a first mask to activate a photoresist dissolving agent generator of a first type to release a first photoresist dissolving agent in the first set of areas. Then, a second set of areas of the photoresist is also exposed to a second light source through a second mask to activate a photoresist dissolving agent generator of a second type to release a second photoresist dissolving agent in the second set of areas. The second set of areas is a sub set of the first set of areas such that the first and second photoresist dissolving agents in the second set of areas neutralize each other to protect the second set of areas from being used as the patterns for forming the openings.

In one example, the photoresist layer contains both a photoacid generator and a photobase generator, and the photoacid generator is activated first. In another example, the photoresist layer contains a photoacid generator and a water-soluble film containing a photobase generator is coated onto the photoresist layer. In yet another example, the photoresist layer contains both a photobase generator and a photoacid generator and the photobase generator is activated first.

Various aspects of the disclosure will become apparent from the following detailed description, taken in conjunction with the accompanying drawings, illustrating by way of example the principles of the disclosure.

### BRIEF DESCRIPTION OF THE DRAWINGS

FIGS. 1A-1F are partial sectional views of semiconductor structures for illustrating the processing steps according to the first example of the present disclosure.

FIGS. 2A-2G are partial sectional views of semiconductor structures for illustrating the processing steps according to the second example of the present disclosure.

FIGS. 3A-3F are partial sectional views of semiconductor structures for illustrating the processing steps according to the third example of the present disclosure.

FIG. 4 presents a flowchart explaining processing steps according to the first example of the present disclosure.

FIG. 5 presents a flowchart explaining processing steps according to the second example of the present disclosure.

FIG. 6 presents a flowchart explaining processing steps according to the third example of the present disclosure.

### DESCRIPTION

In the present disclosure, a packed pattern and an unpacked pattern are utilized to define a photoresist layer pattern. The final pattern has the critically defined dimensions of the packed pattern. A photoresist dissolving agent generator such as a photoacid generator and/or a photobase generator are incorporated into either a single photoresist layer or into a photoresist layer and a water-soluble film. Acid produced by the photoacid generator in the exposed areas is activated during a post-exposure bake. In this disclosure, the undesired holes in the packed pattern are not covered by patterned areas of a second photoresist layer. Instead, the undesired holes in the first photoresist layer are given another different exposure via a second photomask. Chemical base produced by the photobase generator in undesired hole patterns neutralizes acid produced during the previous exposure. The acid, in areas selected to be retained in the final pattern, cleaves the photoresist polymer into smaller and more soluble moieties. These soluble areas are dissolved away by the developer, subsequently producing the final desired pattern.

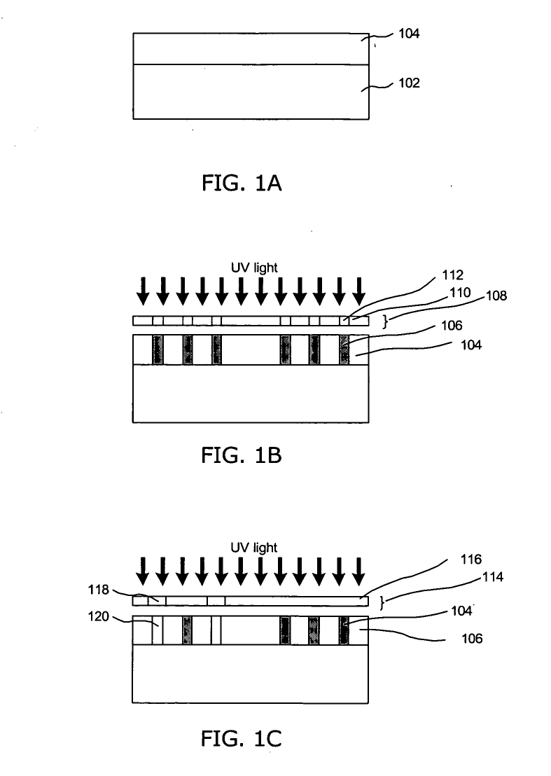

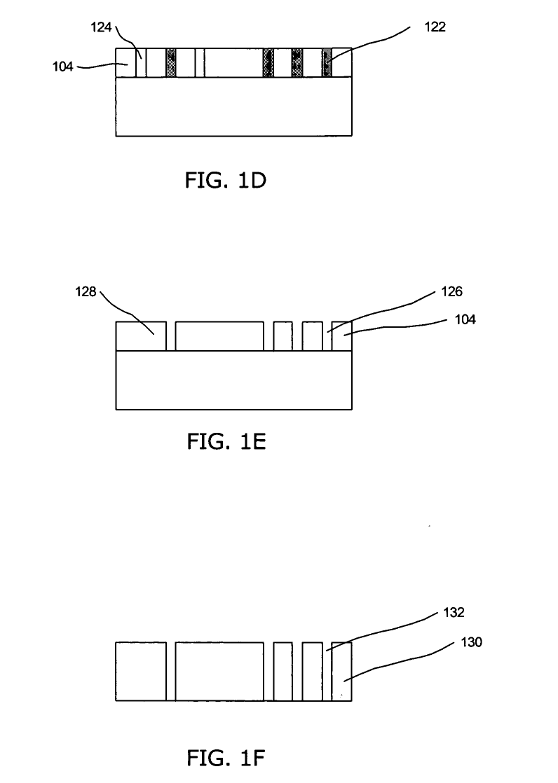

In a first example, FIG. 1A illustrates a substrate 102 coated by a chemically-amplified photoresist 104 containing both a photoacid generator and a photobase generator. In FIG. 1B, ultraviolet (UV) light is utilized to expose areas 106 of the photoresist layer 104, via the photomask 108 with a packed pattern (i.e., the packing mask). Opaque areas 110 of the photomask 108 leave part of the photoresist 104 that are directly underneath unexposed. Clear areas 112 of the photomask 108 expose and activate the photoacid generator in the photoresist layer 104 to generate acid in areas 106, that are directly underneath.

FIG. 1C illustrates the exposure of the same photoresist layer 104 by UV light of either a different wavelength or a longer exposure time via the photomask 114 with an unpacked pattern (i.e., an unpacking mask). Opaque areas 116 of the photomask 114, with an unpacked pattern, leave some areas of the photoresist 104 unexposed. Clear areas 118 of the photomask 114 expose and activate the photobase generator in the photoresist layer 104 to generate a chemical base in areas 120. This base neutralizes the acid that was previously generated. It is noted that areas 120 are a subset of areas 106.

FIG. 1D illustrates the effects of the post-exposure bake. In the photoresist layer 104, areas 122 contain only acid generated from the first exposure via the photomask 108. Areas 124 contain both acid generated from the first exposure via the photomask 108, and also base generated from the second exposure via the photomask 114. In areas 124, the base neutralizes the acid and therefore there is no net effect on the photoresist layer 104 in areas 124 and no pattern is developed there. FIG. 1E illustrates the development of the photoresist layer 104 through which areas 122 are dissolved away in the desired holes 126 only. Areas 124 are undeveloped and therefore photoresist remains there as shown as areas 128. The developed pattern yields open holes in locations defined by the packed pattern of the first photomask 108 minus the locations defined by the unpacked pattern of the second mask 114, but with the critical dimensions of the packed pattern of the first mask 108. FIG. 1F illustrates the etched substrate 130. The desired pattern developed and shown in FIG. 1E is accurately defined in the etched pattern 132 in the substrate.

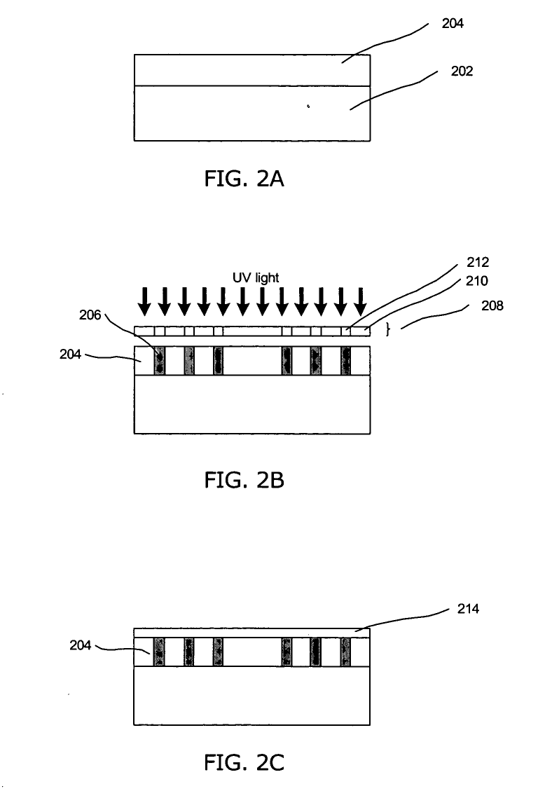

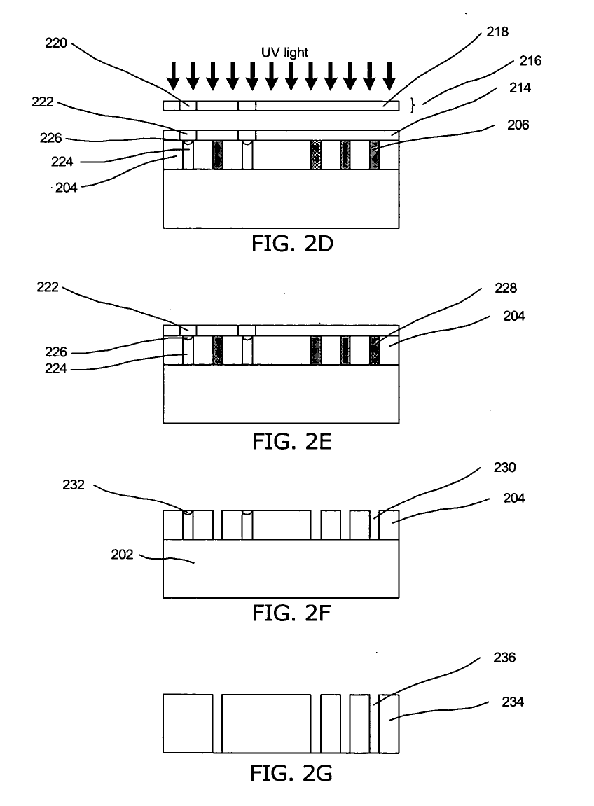

In a second example, FIG. 2A illustrates a substrate 202 coated by a chemically amplified photoresist 204 containing a photoacid generator. In FIG. 2B, UV light is utilized to expose areas 206 of the photoresist layer 204 via the photomask 208 with a packed pattern. Opaque areas 210 of the photomask 208 leave the areas 204 that are directly underneath unexposed. Clear areas 212 of the photomask 208 expose and activate the photoacid generator in the photoresist layer 204 to generate acid in areas 206 that are directly underneath. FIG. 2C illustrates the coating of the undeveloped photoresist layer 204 by a water-soluble film 214 containing a photobase generator (PBG). FIG. 2D illustrates the exposure of the water-soluble film 214 containing a PBG by UV light via photomask 216 with an unpacked pattern. Opaque areas 218 of the photomask 216 leave the water-soluble film 214 unexposed in areas 204. Clear areas 220 of the photomask 216 expose and activate the photobase generator in the water-soluble film to generate a chemical base in areas 222 that diffuses into the areas 224 of the underlying photoresist layer 204. Areas 224 are only the undesired holes in the packed pattern. The chemical base diffuses most heavily into the top of areas 224 producing areas 226. This base neutralizes the acid that was previously generated in the same areas of 206.

FIG. 2E illustrates the effect of a post-exposure bake. In the photoresist layer 204, areas 206 contain only acid generated from the first exposure via the photomask 208. Areas 226 contain both acid generated from the first exposure and also base generated from the second exposure. In areas 226, the base neutralizes the acid and therefore there is no net effect on the photoresist layer 204 in areas 226 and no pattern is developed there. Areas 228 are the only areas of the photoresist layer that contained acid after the first exposure with the photomask with the packed pattern. Post-exposure bake causes the acid to break up the polymer of the photoresist layer into smaller moieties that will be soluble in the aqueous basic develop solution.

FIG. 2F illustrates the dissolution of the water-soluble film and the development of the photoresist layer 204. Areas 228 are dissolved away in the desired holes 230 only. Areas 226 are undeveloped and therefore photoresist remains there as areas 232. The developed pattern yields open holes in locations defined by the packed pattern of the first photomask 208 minus the locations defined by the unpacked pattern of the second photomask 216, but with the critical dimensions of the packed pattern of the first photomask 208. FIG. 2G illustrates the etched substrate 234. The desired pattern developed and shown in FIG. 2F is accurately defined in the etched openings 236 in the substrate 234.

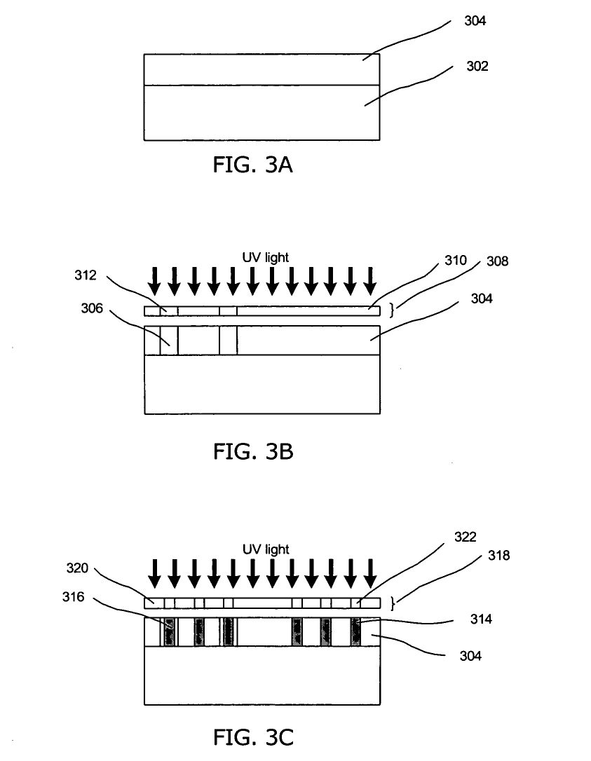

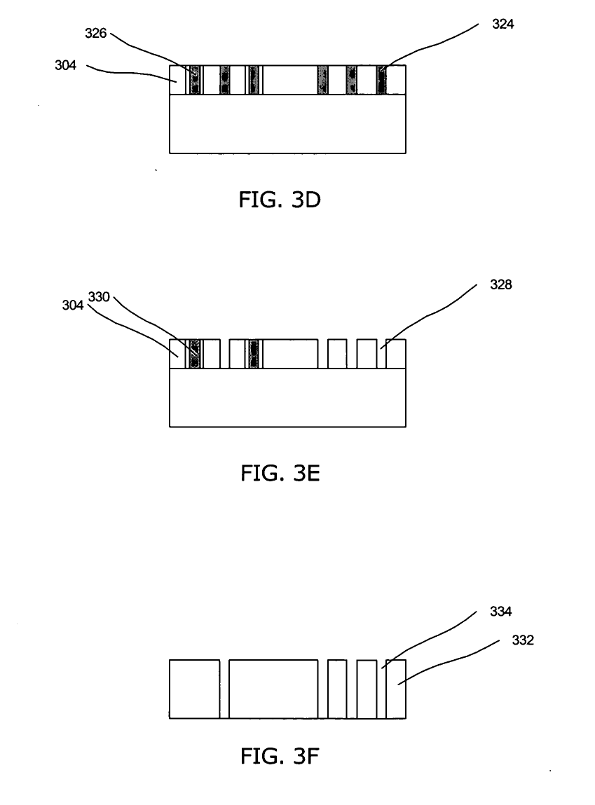

In a third example, FIG. 3A illustrates a substrate 302 coated by a chemically-amplified photoresist 304 containing both a photobase generator and a photoacid generator. In FIG. 3B, UV light, either of a chosen wavelength or with an extended exposure time, is utilized to expose areas 306 of the photoresist layer 304 via the photomask 308 with an unpacked pattern. Opaque areas 310 of the photomask 308 leave the photoresist areas 304, that are directly underneath, unexposed. Clear areas 312 of the photomask 308 expose and activate the photobase generator in the photoresist layer 304, with a chosen UV wavelength or an extended exposure time, to generate a chemical base in areas 306 that are directly underneath. FIG. 3C illustrates the exposure of areas 314 and 316 of the same photoresist layer 304 by UV light via the photomask 318 with a packed pattern. Opaque areas 320 of the photomask 318, with a packed pattern, leave the photoresist 304 unexposed. Clear areas 322 of the photomask 318 expose and activate the photoacid generator in the photoresist layer 304 to generate acid in the areas 314 and 316. In areas 316, the acid is neutralized by the chemical base previously generated there by the exposure shown in FIG.3B. It is understood that areas 316 may be subsets of areas 314. FIG. 3D illustrates the effects of the post-exposure bake. In the photoresist layer 304, areas 324 contain only acid generated from the second exposure via the photomask 318. Areas 326 contain both acid generated from the second exposure via photomask 318, and also chemical base generated from the first exposure via photomask 308. In areas 326, the base neutralizes the acid and therefore there is no net effect on the photoresist layer 304 in areas 326 and no pattern is developed there.

FIG. 3E illustrates the development of photoresist layer 304. Areas 324 are dissolved away in the desired holes 328 only. Areas 326 are undeveloped and therefore photoresist remains there as areas 330. The developed pattern yields open holes in locations defined by the packed pattern of the second photomask 318 minus certain locations defined by the unpacked pattern of the first photomask 308, but with the critical dimensions of the packed pattern of the second photomask 318. FIG. 3F illustrates the etched substrate. The desired pattern developed and shown in FIG. 3E is accurately defined in the substrate 332 with opened areas 334.

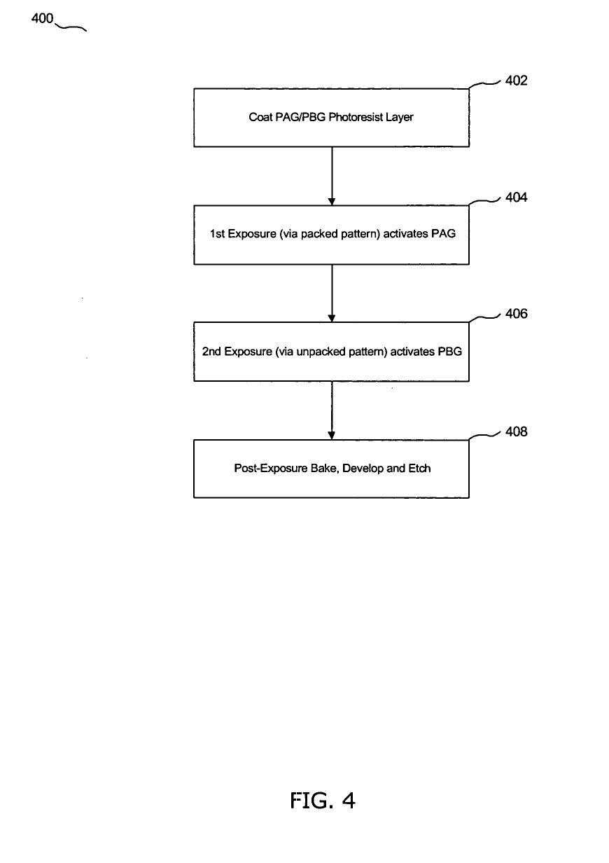

FIG. 4 is a flow chart 400 illustrating the processes according to the first example. In FIG. 4 the coating of a substrate by a chemically-amplified photoresist containing both a photoacid generator (PAG) and a photobase generator (PBG) is done in step 402.

The first exposure, by ultraviolet (UV) light, via a photomask with a packed pattern, of the photoresist layer is done in step 404. The packed pattern contains both the desired holes and the padding or undesired holes. Acid is generated in the exposed hole patterns.

The second exposure by ultraviolet (UV) light, via a photomask with an unpacked pattern, of the same photoresist layer is done in step 406. The unpacked pattern contains only the undesired holes. Chemical base is generated in the exposed hole pattern.

The post-exposure bake of the photoresist layer, the development of the photoresist layer, and the etching of the substrate are all processed in step 408. The bake activates the acid in the desired hole patterns, and so those areas become soluble in the developer solution. In the undesired hole patterns, the acid is neutralized by the chemical base and therefore there is no net effect on those photoresist areas and no patterns are developed there. The etch process produces the desired hole pattern in the substrate.

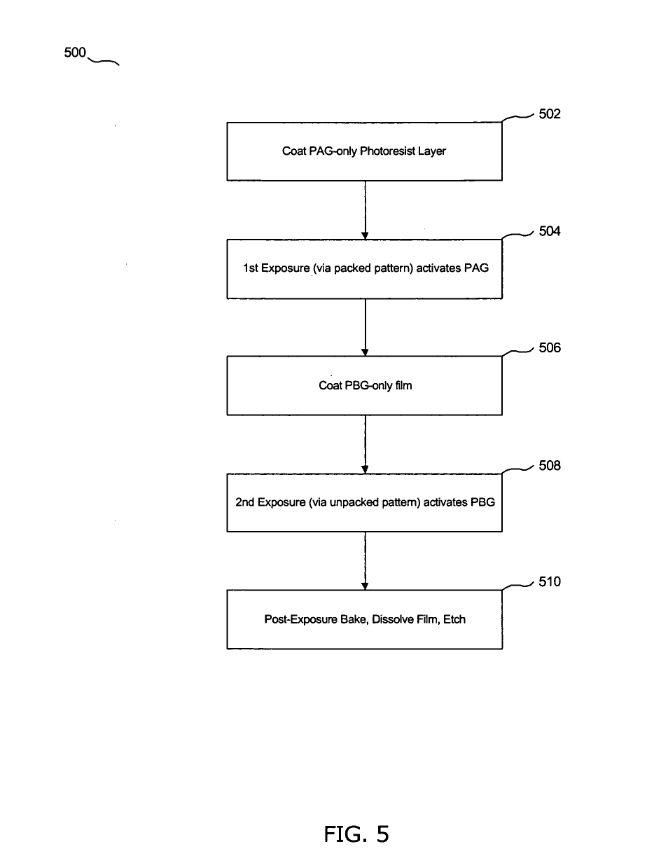

FIG. 5 is another flow chart 500 representing the processes of the second example. In step 502, the coating of a substrate by a chemically-amplified photoresist containing a photoacid generator (PAG) is done.

The first exposure, by ultraviolet (UV) light, via a photomask with a packed pattern, of the photoresist layer is done on step 504. The packed pattern contains both the desired holes and the padding or undesired holes. Acid is generated in the exposed hole patterns.

The coating of the undeveloped photoresist layer by a water-soluble film that contains a photobase generator is completed in step 506.

The second exposure, by UV light, via a photomask with an unpacked pattern, of the water-soluble film is carried out in step 508. The unpacked pattern contains only the undesired hole patterns. Chemical base is generated in the exposed hole pattern.

The post-exposure bake, dissolution of the water-soluble film, development of the photoresist layer, and the etching of the substrate are all processed in step 510. Post-exposure bake activates the acid only in the desired hole pattern. In the undesired hole pattern, the acid is neutralized by the chemical base so that no pattern is produced there.

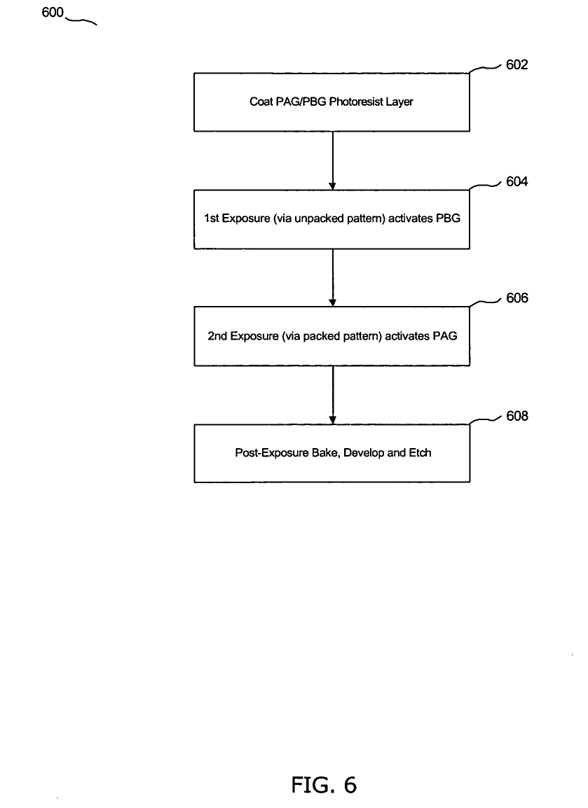

FIG. 6 is another flow chart 600 corresponding to the third example. In step 602, the coating of a substrate by a chemically-amplified photoresist containing both a photobase generator (PBG) and a photoacid generator (PAG) is completed.

The first exposure, by ultraviolet (UV) light, via a photomask with an unpacked pattern, of the photoresist layer is done in step 604. The unpacked pattern contains only the undesired holes. Chemical base is generated in the exposed hole pattern.

The second exposure, by ultraviolet (UV) light, via a photomask with a packed pattern, of the same photoresist layer is done on step 606. The packed pattern contains both the desired holes and the padding or undesired holes. Acid is generated in the exposed hole patterns.

The post-exposure bake of the photoresist layer, the development of the photoresist layer, and the etching of the substrate are done in step 608. The bake activates the acid in the desired hole patterns and so those areas become soluble in the developer solution. In the undesired hole patterns, the acid is neutralized by the chemical base and therefore there is no net effect on those photoresist areas and no patterns are developed there. The etch process produces the desired hole patterns in the substrate.

The above disclosure provides many different embodiments, or examples, for implementing different features of the disclosure. Specific examples of components, and processes are described to help clarify the disclosure. These are, of course, merely examples and are not intended to limit the disclosure from that described in the claims.

Although illustrative embodiments of the disclosure have been shown and described, other modifications, changes, and substitutions are intended in the foregoing disclosure. Accordingly, it is appropriate that the appended claims be construed broadly and in a manner consistent with the scope of the disclosure, as set forth in the following claims.

1. A method for selectively forming photoresist patterns for making openings in a substrate, the method comprising:
depositing a layer of photoresist on the substrate having one or more types of photoresist dissolving agent generators;
exposing a first set of areas of the photoresist to a first light source through a first mask to activate a photoresist dissolving agent generator of a first type to release a first photoresist dissolving agent in the first set of areas; and
exposing a second set of areas of the photoresist to a second light source through a second mask to activate a photoresist dissolving agent generator of a second type to release a second photoresist dissolving agent in the second set of areas,
wherein the second set of areas is a sub set of the first set of areas such that the first and second photoresist dissolving agents in the second set of areas neutralize each other to protect the second set of areas from being used as the patterns for forming the openings.

2. The method of claim 1 wherein the photoresist dissolving agent generator of the first type is a photoacid generator and the first photoresist dissolving agent is a photoacid, and the photoresist dissolving agent generator of the second type is a photobase generator and the second photoresist dissolving agent is a photobase.

3. The method of claim 1 wherein the photoresist dissolving agent generator of the first type is a photobase generator and the first photoresist dissolving agent is a photobase, and the photoresist dissolving agent generator of the second type is a photoacid generator and the second photoresist dissolving agent is a photoacid.

4. The method of claim 1 wherein the first and second light sources provide a light of the same wavelength.

5. The method of claim 1 wherein the first and second light sources provide lights of different wavelengths.

6. The method of claim 1 further comprising a bake process after the exposure to the second light source.

7. The method of claim 1 further comprising forming the openings in the substrate using the photoresist after the exposure to the second light source.

8. The method of claim 7 wherein the forming further includes:
developing and dissolving the photoresist in the first set of areas but not in the second set of areas;
removing the dissolved photoresist; and
forming the openings in the substrate underneath the removed photoresist.

9. A method for selectively forming photoresist patterns for making openings in a substrate, the method comprising:
depositing a layer of photoresist on the substrate having a first type of photoresist dissolving agent generator;
exposing a first set of areas of the photoresist to a first light source through a first mask to activate the first type of photoresist dissolving agent generator for releasing a first photoresist dissolving agent in the first set of areas;
coating a film containing a second type of photoresist dissolving agent generator;
exposing a second set of areas of the film to a second light source through a second mask to activate the second type of photoresist dissolving agent generator for releasing a second photoresist dissolving agent in the second set of areas,
wherein the second set of areas overlap one or more predetermined areas of the first set such that the second photoresist dissolving agent in the second set of areas neutralizes the first photoresist dissolving agent in the predetermined areas of the first set to protect the predetermined areas of the first set in the photoresist from being used as the patterns for forming the openings.

10. The method of claim 9 wherein the photoresist dissolving agent generator of the first type is a photoacid generator and the first photoresist dissolving agent is a photoacid, and the photoresist dissolving agent generator of the second type is a photobase generator and the second photoresist dissolving agent is a photobase.

11. The method of claim 9 wherein the photoresist dissolving agent generator of the first type is a photobase generator and the first photoresist dissolving agent is a photobase, and the photoresist dissolving agent generator of the second type is a photoacid generator and the second photoresist dissolving agent is a photoacid.

12. The method of claim 9 wherein the first and second light sources provide a light of the same wavelength.

13. The method of claim 9 wherein the first and second light sources provide lights of different wavelengths.

14. The method of claim 9 further comprising a bake process after the exposure to the second light source.

15. The method of claim 9 further comprising forming the openings in the substrate using the photoresist after the exposure to the second light source.

16. The method of claim 15 wherein the forming further includes:
developing and dissolving the photoresist in the first set of areas but not in the second set of areas;
removing the dissolved photoresist; and
forming the openings in the substrate underneath the removed photoresist.

17. A method for selectively forming photoresist patterns for making openings in a substrate using a packing-and-unpacking process, the method comprising:
depositing a layer of photoresist on the substrate having one or more types of photoresist dissolving agent generators;
using a packing mask for exposing a first set of areas of the photoresist to a first light source to activate a photoresist dissolving agent generator of a first type to release a first photoresist dissolving agent in the first set of areas; and
using an unpacking mask for activating a photoresist dissolving agent generator of a second type to release a second photoresist dissolving agent to neutralize the first photoresist dissolving agent in one or more predetermined areas within the first set of the areas, thereby protecting the one or more predetermined areas from being used as the patterns for forming the openings.

18. The method of claim 17 wherein the photoresist dissolving agent generator of the second type is embedded in the photoresist.

19. The method of claim 18 wherein the using an unpacking mask further includes exposing the predetermined areas of the photoresist to a second light source.

20. The method of claim 17 wherein the photoresist dissolving agent generator of the second type is embedded in a coating film formed over the photoresist after using the packing mask.

21. The method of claim 20 wherein the using an unpacking mask further includes exposing a second set of areas of the coating film to a second light source, the second set of areas of the coating film being on top of the predetermined areas of the photoresist.

22. The method of claim 20 wherein the coating film is water soluble.

23. The method of claim 17 further comprising baking the photoresist to enhance the neutralization of the photoacid and photobase.
